(19) United States
(12) Patent Application Publication
(10) Pub. No.: US 2021/0358649 A1
(43) Pub. Date: Nov. 18, 2021

(54) SYSTEMS AND METHODS FOR LASER DRIVEN NEUTRON GENERATION FOR A LIQUID-PHASE BASED TRANSMUTATION

(71) Applicant: TAE TECHNOLOGIES, INC., Foothill Ranch, CA (US)

(72) Inventors: Toshiki Tajima, Foothill Ranch, CA (US); Ales Necas, Greensboro, NC (US)

(21) Appl. No.: 17/193,932

(22) Filed: Mar. 5, 2021

Related U.S. Application Data
(63) Continuation of application No. PCT/US19/49820, filed on Sep. 5, 2019.
(60) Provisional application No. 62/876,999, filed on Jul. 22, 2019.
(60) Provisional application No. 62/774,427, filed on Dec. 3, 2018.
(60) Provisional application No. 62/727,413, filed on Sep. 5, 2018.

(51) Int. Cl. G21F 9/30; G21F 9/02

(52) U.S. Cl. CPC G21F 9/301; H01S 5/02212; G21F 9/02

(57) ABSTRACT

Systems and methods that facilitate the transmutation of long-lived radioactive transuranic waste into short-live radioactive nuclides or stable nuclides using pre-pulse lasers to irradiate carbon nanotubes (CNTs) saturated with tritium into ionized gas of carbon and tritium and a laser-driven particle beam to fuse with the tritium and generate neutrons.

### CROSS-REFERENCE TO RELATED APPLICATIONS

The subject application is a continuation of PCT Patent Application No. PCT/US19/49820, filed Sep. 5, 2019, which claims priority to U.S. Provisional Patent Application No. 62/876,999, filed on Jul. 22, 2019, U.S. Provisional Patent Application No. 62/774,427, filed on Dec. 3, 2018, and U.S. Provisional Patent Application No. 62/727,413, filed on Sep. 5, 2018, all of which are incorporated by reference herein in their entireties for all purposes.

### FIELD

The subject matter described herein relates generally to systems and methods that facilitate the generation of a large rate of energetic neutrons by laser driven beam for purposes of transmutation of long-lived high-level radioactive waste (trans-uranic and fission products) into short-lived radioactive nuclides or stable nuclides, and, more particularly, to a subcritical liquid phase-based transmutation of radioactive waste.

### BACKGROUND

Nuclear fission reactors generate a constant stream of radioactive nuclides of the spent fuel: in United States alone 90,000 metric tons requires disposal [Ref. 1], and by 2020 the worldwide spent nuclear waste inventory will reach 200,000 metric tons with 8000 tons added each year. Nuclear power accounts for 77% of electricity in France, making the need for transmutation particularly acute. Currently, there are no proper and adequate means available to treat these isotopic radioactive materials other than deep earth burial. The development of such means to treat isotopic radioactive materials requires the completion of two tasks: First, developing easy, robust, safe, and inexpensive methods to separate highly radioactive isotopes from the rest of the materials in order to avoid activating the non-radioactive material through transmutation; and, second, developing a safe, inexpensive, energy non-exhaustive, versatile transmutation method.

Current approaches to transmutation of radioactive nuclei include drivers that maintain the subcritical fission reactor by an external means: one is based on an accelerator driven system (ADS) [Ref. 2], and the other is based on tokamak driven systems [Ref. 3]. The ADS system relies on a highly energetic (˜1 GeV) proton beam impinging on a substrate (e.g. Pb, W) and ejecting neutrons (30+ neutrons per proton). These neutrons then maintain fission in a subcritical reactor. The tokamak-based system generates neutron from the deuterium-tritium reactions and uses these neutrons to drive the subcritical reactor, also called the fission-fusion hybrid.

Other approaches to transmuting nuclear waste based on a supercritical operation also exist—MOSART [Ref. 4], as well as various approaches using the Gen-IV reactors.

For these and other reasons, needs exist for improved systems, devices, and methods that facilitates generation of a large rate of energetic neutrons by laser driven beam for purposes of subcritical liquid phase-based transmutation of radioactive waste.

### SUMMARY

The various embodiments provided herein are generally directed to systems and methods that facilitate transmutation of long-lived high-level radioactive waste by means of fusion generated neutrons into short-lived radioactive nuclides or stable nuclides. Neutrons are generated by fusion of a deuterium beam and either tritium or deuterium targets whereas the deuterium beam is laser accelerated by a main laser using a process known as Coherent Acceleration of Ions by Laser (CAIL) [Ref. RAST, 6].

In example embodiments, a transmutation process employees a subcritical method of operation utilizing a compact device to transmute radioactive isotopes (mainly those of minor actinides (MA)) carried out in a tank containing a liquefied solution of a mix of the spent fuel waste components (such as the fission products (FP) and MA) dissolved within molten salt solution of LiF-BeF2 (FLiBe). [Ref. 5] Transmutation of the MA is performed with energetic neutrons originating from a fusion reaction driven by a laser. Monitoring and control in real-time of the FLiBe, MA and FP content within the transmutator is performed with active laser spectroscopy or a laser driven gamma source.

In further example embodiments the target is formed from tritium saturated carbon nanotubes.

In further example embodiments the deuterium or tritium targets are laser-ionized gas of almost solid density. To form these targets, a pre-pulse laser (prior to the main laser) ionizes the target [Ref 7 and 8]. While the target remains at solid density, CAIL accelerated deuterons fuse with the tritium or deuterium.

In further example embodiments the transmutation tank is maintained subcritical at all times. The subcritical operation places a burden on the neutron sources whereas energetic neutrons are produced in the intimately coupled arrangement: (1) By irradiating a nanometric foil composed of diamond and deuteron to form deuterium beam by the CAIL process. (2) Injecting the accelerated deuterium into a nanometrically “foamy” tritium-saturated target synchronously and dynamically ionized by a pre-pulse laser.

Advantages of the example embodiments of laser generated neutrons include:
a) Small size of the laser-driven ion beams and their targets
b) Fine neutron control: temporal as well as spatial. All fuel (MA) is within one fission mean-free-path of the neutron source.
c) High repetition rate of the laser.
d) High laser wall plug efficiency of 30%.

In example embodiments, the laser architecture, as described in the previous paragraph, is configured to provide pulses with, e.g., <10 fs pulse energy of 10 mJ over 20 μm spot size, leading to an optimum a₀=0.5. The pump pulse for the optical parametric chirped-pulse amplification (“OPCPA”) will be provided by a coherent amplification network (CAN) laser making possible very high pump pulse repetition rate up to 100 kHz. The femtosecond pulses are produced by a femtosecond oscillator delivering over a million pulses per second. After the oscillator, the pulses are picked up at the desired rate of up to 100 kHz before being stretched to a few nanoseconds. After stretching, the pulse is amplified in a cryogenic OPCPA to a level of tens of mega Joules. The cryogenic OPCPA preferably exhibits an extremely high thermal conductivity comparable to copper, which is necessary to evacuate the tens of kilo Watts of thermal load produced during the optical parametric amplification process. With the spectral bandwidth corresponding to less than a 10 fs pulse, the pulse can be easily stretched to about one nanosecond and amplified by optical parametric amplification to 10 mJ. In the process the pulse is mixed with the pump pulse provided by the CAN system of about a ns duration and >10 mJ energy. The amplified chirped pulse is them compressed back to its initial value of <10 fs.

In the various embodiments provided herein, the transmutation of low level radioactive waste (“LLRW”) occurs in a liquid state whereas the LLRW is dissolved in a molten salt of lithium fluoride beryllium fluoride (FLiBe).

In the various embodiments provided herein, the transmutation machine operates in a subcritical mode whereas the neutron source is required at all times to drive the transmutation.

In certain example embodiments, the laser monitoring via laser-spectroscopy is carried out by a CAN laser [Ref 12].

In addition, a laser-driven gamma source (commonly called laser Compton gamma-rays) is provided to track the content and behavior of isotopes of MA and FP in the tanks in real-time.

A further embodiment is directed to a 2-tank strategy to reduce the overall neutron cost whereas one tank is critical and the other tank is subcritical. The two tanks comprise two interconnected sets of tanks. The first tank or set of tanks preferably contains a mixture of Pu and minor actinides (MA) including neptunium, americium and curium (Np, Am, Cm), while the second tank or set of tanks contains a mixture of only minor actinides (MA). Since the first tank or set of tanks is critical (k_{eff}=1), an external source of neutrons is unnecessary. Furthermore, the first tank or set of tanks is fueled using the spent nuclear fuel (Pu and MA) after chemical removal of fission products. The first tank or set of tanks utilizes fast neutrons (fusion neutrons in addition to unmoderated fission neutrons with energy >1 MeV) to transmute the minor actinides (MA) and plutonium (Pu), while the concentration of curium (Cm) is increased. Alternatively, a minor amount of neutrons can be injected into the first tank or set of tanks to kick start the incineration of Pu.

In a further embodiment the walls of the first and second tank or set of tanks are made of carbon based materials, such as, e.g., diamond. To protect walls from chemical erosion and corrosion, the salt adjacent to the wall (facing the molten salt) is allowed to solidify preventing direct contact of the molten salt with the walls.

In a further embodiment, the transmutator embodiments described above can be applied to the methods and processes of carbon dioxide reduction such as its use as a coolant and its generation of a synthetic fuel to become overall carbon-negative is suggested. In the following example embodiment, the synthetic fuel (CH₄—methane) may be generated via CO₂+4H₂→CH₄+2H₂O reaction (Sabatier reaction) requiring 200-400° C. and the presence of a catalyst, e.g., Ni, Cu, Ru. The CO₂ may be extracted from the atmosphere, the ocean, or by direct capturing of CO₂ at the source of emission such as automobiles, houses, chimneys and smokestacks. The molten salt transmutator operating temperature range is 250-1200° C. and, thus, is ideally situated to supply continuously the necessary temperature required to drive the Sabatier reaction to produce methane, and provide an effective pathway to stabilize and reduce the CO₂ concentration in the atmosphere and the ocean.

Other systems, devices, methods, features and advantages of the subject matter described herein will be or will become apparent to one with skill in the art upon examination of the following figures and detailed description. It is intended that all such additional systems, methods, features and advantages be included within this description, be within the scope of the subject matter described herein, and be protected by the accompanying claims. In no way should the features of the example embodiments be construed as limiting the appended claims, absent express recitation of those features in the claims.

### BRIEF DESCRIPTION OF FIGURES

The details of the example embodiments, including structure and operation, may be gleaned in part by study of the accompanying figures, in which like reference numerals refer to like parts. The components in the figures are not necessarily to scale, emphasis instead being placed upon illustrating the principles of the disclosure. Moreover, all illustrations are intended to convey concepts, where relative sizes, shapes and other detailed attributes may be illustrated schematically rather than literally or precisely.

FIG. 1A illustrates a perspective view of an axially segmented transmutator vessel.

FIG. 1B illustrates a cross sectional view of an azimuthally segmented transmutator vessel.

FIG. 2A illustrates perspective views of a neutron source and a single adjacent tank whereas neutrons generate from DT fusion. Tritium is present as a gas and deuteron is created via laser-foil interaction within a keyhole. Keyholes are located on the entrance window.

FIG. 2B illustrates a single keyhole assembly.

FIG. 3A illustrates perspective views of a neutron source and a single adjacent tank whereas neutrons generate from DT fusion. In this embodiment deuteron is generated via laser-foil interaction and tritium forms a solid target at the back of the keyhole. Neutrons are generated whereas deuterons interact with tritium within the solid target. Keyholes are located within the neutron source tank.

FIG. 3B illustrates a single keyhole assembly.

FIG. 4 illustrates a schematic diagram a laser accelerator system by the main laser and an ionizing chamber by pre-pulse laser for neutron generation.

FIG. 5 illustrates a schematic diagram of laser generation for the laser accelerator system.

FIG. 6 illustrates a side view of a liquid phase based transmutation system with laser assisted separation and monitoring.

FIG. 7 illustrates a partial detail view of a central solution tank of the liquid phase based transmutation system with laser assisted separation and monitoring shown in FIG. 6.

FIG. 8 illustrates a side view of an alternative embodiment of a two-step liquid phase based separation and transmutation system with laser assisted separation and monitoring.

FIG. 9 illustrates an embodiment directed to a 2-tank strategy to reduce the overall neutron cost whereas Tank 1 is critical and Tank 2 subcritical.

FIGS. 10 illustrates an embodiment directed to a process of the generation of synthetic fuel by the chemical conversion of CO_2 whereas the heat to drive the reaction is generated by fission.

FIGS. 11 illustrates another embodiment directed to a process of the generation of synthetic fuel by the chemical conversion of CO_2 whereas the heat to drive the reaction is generated by fission.

FIGS. 12 illustrates another embodiment directed to a process of the generation of synthetic fuel by the chemical conversion of CO_2 whereas the heat to drive the reaction is generated by fission.

FIGS. 13 illustrates another embodiment directed to a process of the generation of synthetic fuel by the chemical conversion of CO_2 whereas the heat to drive the reaction is generated by fission.

It should be noted that elements of similar structures or functions are generally represented by like reference numerals for illustrative purpose throughout the figures. It should also be noted that the figures are only intended to facilitate the description of the preferred embodiments.

### DETAILED DESCRIPTION

Each of the additional features and teachings disclosed below can be utilized separately or in conjunction with other features and teachings to provide systems and methods that facilitate the transmutation of long-lived radioactive waste into short-live radioactive nuclides or stable nuclides utilizing a laser-driven fusion approach to the generation of neutrons.

Moreover, the various features of the representative examples and the dependent claims may be combined in ways that are not specifically and explicitly enumerated in order to provide additional useful embodiments of the present teachings. In addition, it is expressly noted that all features disclosed in the description and/or the claims are intended to be disclosed separately and independently from each other for the purpose of original disclosure, as well as for the purpose of restricting the claimed subject matter independent of the compositions of the features in the embodiments and/or the claims. It is also expressly noted that all value ranges or indications of groups of entities disclose every possible intermediate value or intermediate entity for the purpose of original disclosure, as well as for the purpose of restricting the claimed subject matter.

In example embodiments, a transmutation process employees a subcritical method of operation utilizing a compact device to transmute radioactive isotopes (mainly those of minor actinides (MA)) carried out in a tank containing a liquefied solution of a mix of the spent fuel waste components (such as the fission products (FP) and MA) dissolved within molten salt solution of LiF-BeF2 (FLiBe). Such process is described in U.S. Provisional Patent Application No. 62/544,666 [Ref. 5], which is incorporated herein by reference. Transmutation of the MA is performed with energetic neutrons originating from a fusion reaction driven by a laser. Monitoring and control in real-time of the FLiBe, MA and FP content within the transmutator is performed with active laser spectroscopy or a laser driven gamma source.

In example embodiments provided herein, the neutrons are generated by laser driven fusion to transmute long lived radioactive nuclei into short-lived or non-radioactive nuclides.

In further example embodiments the deuterium or tritium targets are laser-ionized gas of almost solid density. To form these targets, a pre-pulse laser (prior to the main laser) ionizes the target [Ref 7 and 8]. While the target remains at solid density, CAIL accelerated deuterons fuse with the tritium or deuterium.

In further example embodiments the transmutation tank is maintained subcritical at all times. The subcritical operation places a burden on the neutron sources whereas energetic neutrons are produced in the intimately coupled arrangement: (1) By irradiating a nanometric foil composed of diamond and deuteron to form deuterium beam by the process known as Coherent Acceleration of Ions by Laser (CAIL). (2) Injecting the accelerated deuterium into a nanometrically “foamy” tritium-saturated target synchronously and dynamically ionized by a pre-pulse laser.

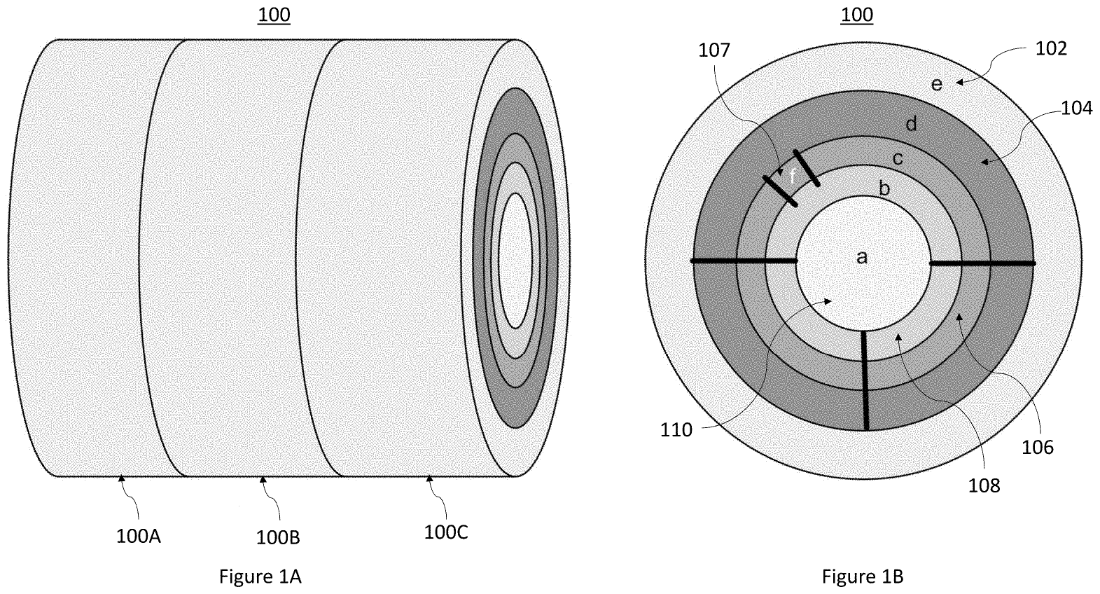

Turning to the figures, FIGS. 1A and 1B show a segmented transmutator vessel 100. FIG. 1A shows a representative case of axial radial segmentation of the vessel 100 into three (3) vessel sections 100A, 100B and 100C. FIG. 1B shows a representative cross-section of the radial and azimuthal segmentation of the vessel 100. The transmutator vessel 100 in the present embodiment is radially segmented into concentric cylindrical chambers or tanks 102, 104, 106, 108 and 110. An azimuthally segmented chamber 107 shows a representative chamber used for either diagnostics or for additional source of neutrons. By segmenting the vessel 100, control and localization of various parameters can be increased more easily and/or more precisely, as well as increase the overall transmutator safety by data feedback from various segments via an artificial neural network to control valves to adjust minor actinide concentration. Such precise control optimizes the most minor actinide burned while remaining safe.

The tank or chamber 110 is a pressurized gas chamber composed of deuterium or tritium gas and functions as the neutron source to ignite the self-sustaining chain reaction in the first and second concentric tanks 108 and 106. The first and second tanks 106 and 108 contain a mixture of FLiBe molten salt and minor actinides. The third concentric tank 104 contains fission products that are transmuted into stable or short-lived nuclides. The fourth concentric tank 102 is a graphite reflector.

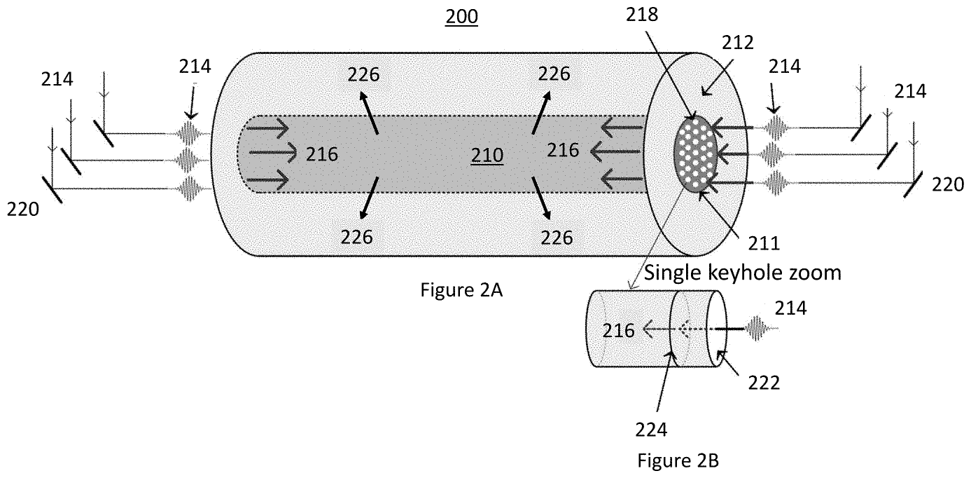

FIG. 2A shows a partial view of a single assembly of a transmutator 200 having a tank 212 and a neutron source tank 210 positioned therein. Additional tanks, as shown in FIGS. 1A, 1B may enclose the tank 212. In this embodiment, a laser pulse 214 is projected onto a mirror 220 and is directed by the mirror 220 toward and into a keyhole 218. A plurality of individual laser pulses 214 and keyhole chambers 218, such as, e.g., thousands (1000s) of laser pulses and keyhole chambers, are provided. An enlarged detail view of an individual keyhole chamber 218 is shown in FIG. 2B. The keyhole 218 is held at a vacuum. A laser pulse 214 passes through a laser window 222 and irradiates a nanometric foil member 224. The nanometric foil member 224 is made of a deuterated diamond and is one or more nano-meters thick, and preferably about 1-10, nano-meters thick. A physical process known as coherent acceleration of ions (CAIL) [see, e.g., Ref. 9 and Ref. 24] accelerates the deuteron and carbon ions from the nanometric foil member 224 as a deuteron beam 216 in a direction toward a center of the neutron source tank 210. The maximum achieved energy is given by equation 1.0 [see, e.g., Ref. 10; Ref. 11]:

ϵₘₐₓ=(2α+1)Qmc²(\sqrt{a₀²+1}−1) 1.20

Where alpha is typically=3, mc²=0.511 MeV, a₀˜0.5 depending on other conditions. Therefore, for deuterium the maximum energy is 0.41 MeV and for carbon ions 2.5 MeV. The deuteron beam 216 fuses with tritium in the neutron source tank 210 generating neutrons 226.

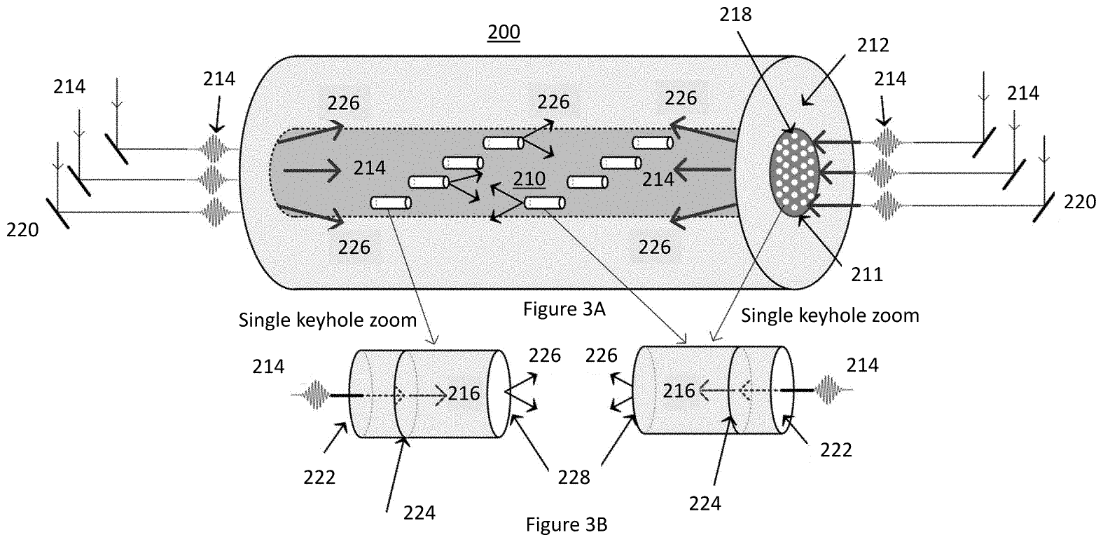

FIGS. 3A and 3B show an alternative embodiment of neutron generation. The physical process of CAIL to accelerate deuteron as a deuteron beam 216 as discussed above with regard to FIGS. 2A and 2B is still used. As depicted in FIG. 3A, the single assembly of a transmutator 200 includes a tank 212 and a neutron source tank 210 positioned therein. Additional tanks, as shown in FIGS. 1A and 1B may enclose the tank 212. In this embodiment, as in the previous embodiment, a laser pulse 214 is projected onto a mirror 220 and is directed by the mirror 220 toward and into a keyhole 218. A plurality of individual laser pulses 214 and keyhole chambers 218, such as, e.g., thousands (1000s) of laser pulses and keyhole chambers, are provided. An enlarged detail view of an individual keyhole chamber 218 is shown in FIG. 3B. The keyhole 218 is held at a vacuum. A laser pulse 214 passes through a laser window 222 and irradiates a nanometric foil member 224. The nanometric foil member 224 is made of deuterated diamond and is about one or more nano-meters thick. The CAIL process accelerates the deuteron and carbon ions from the nanometric foil member 224 as a deuteron beam 216. Instead of being injected into the neutron source tank 210, the deuteron beams 216 are injected onto a solid titanium-tritium target 228 at a back end of the keyhole 218 resulting in neutrons 226 being emitted. The keyholes 218 are positioned at the entrance window 211 to the neutron source tank 210, as well as within the neutron source tank 210. The laser pulse 214 enters the keyhole 214 via the entrance window 222 and interacts with the nanometric foil 224 creating a deuteron beam 216.

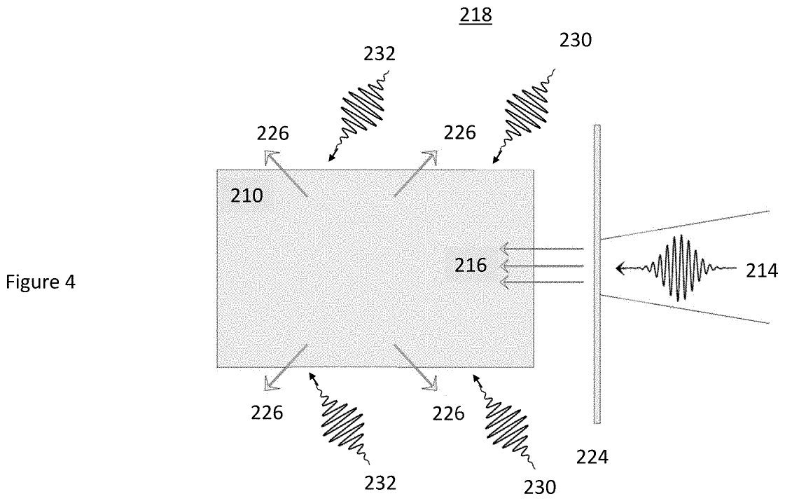

FIG. 4 illustrates in detail the laser-foil interaction in a single keyhole 218 as shown in FIGS. 2B and 3B. As depicted, the laser pulse 214 already having passed through the laser entrance window 222 (see FIGS. 2B and 3B). The laser pulse 214, such as, e.g., from a CAN laser [Ref. 12], irradiates the nanometric foil 224 resulting in the CAIL by the ponderomotive force in mainly a forward direction beyond the electrostatic pull-back force of the foil 224. A longitudinal electric field (not shown) then accelerates deuteron and carbon beam 216 into the pressurized gas chamber 210 (see, e.g., FIGS. 2A and 3A). The accelerated deuterium beam 216 collides and fuses with the tritium gas within the chamber 210 thereby generating energetic neutrons 226, such as, e.g., neutrons having energies of about 14 MeV. The neutrons 226 emanate isotropically and fission of the minor actinides occurs in the tanks (see, e.g., tanks 108 and 106, FIGS. 1A and 1B; tank 212, FIGS. 2A and 3A) surrounding the neutron source tank (see, e.g., tank 110, FIGS. 1A and 1B; tank 210, FIGS. 2A and 3A).

In an alternative embodiment, the neutron source tank 210 is composed of carbon nanotubes (CNTs) saturated with tritium. Pre-pulse lasers 230 and 232 irradiates and penetrate the tank 210 with a laser energy in the Above-Threshold Ionization regime ionizing the CNTs saturated with tritium [Ref. 7; Ref. 8] and maintaining the ionized gas of carbon and tritium at almost solid density for a short time for the deuteron beam to fuse with the ionized tritium plasma at almost solid density. Lasers 230 and 232 are distinct from the main laser 214 used for deuteron acceleration. The laser main pulse (which accelerates deuterons) and the pre-pulse lasers (for CNTs+tritium ionization) must be synchronized so that the deuteron beam lags the pre-pulse and ionization occurs just ahead of the deuteron beam. In this synchronization scheme, the pre-pulse lasers 230 are fired ahead of the pre-pulse lasers 232. This approach provides highly efficient way to convert deuterium-tritium into fast neutrons. The energy example numbers for the pre-pulse ionization laser is estimated 100-300 mJ for a CNT density of 10²² 1/cc, laser spot size 10⁻⁷ cm², and irradiated length of 100 cm.

In an alternative embodiment, single-cycle laser acceleration [Ref 13; Ref. 14] may also be used.

In an alternative embodiment, the gas neutron source tank 210 in FIG. 2A is replaced with a deuterium gas.

In an alternative embodiment, the solid titanium-tritium target 228 in FIG. 3B is replaced with titanium-deuterium target.

In an alternative embodiment, the solid titanium-tritium target 228 in FIG. 3B is replaced with titanium. The deuteron beam 216, interacts with the titanium solid target 228 and remains imbedded within its lattice, subsequent deuterons in the beam 216 collide and fuse with the already imbedded deuteron to generate neutrons 226.

In example embodiments, the laser design parameters, which are estimated from the prior art [Ref. 15], include: intensity I=10¹⁷ W/cm²; laser wavelength=1 μm; pulse duration=5-10 fs; beam width=5-10 μm. The laser is linearly polarized. Additionally, the thickness of the foil 224 (see FIGS. 2B, 3B, 4A and 4B) is preferably provided by equation 2.0:

$$d = λ {a}_{0} \int \frac{{n}_{cr} ( λ )}{{n}_{e} ( x )} dx \qquad 2.0$$

where, the critical density, n_{cr}π/(rₑλ²),

$${a}_{0} = \sqrt{\frac{I}{I 0}} {( μ m / λ )}^{2} , \\ {r}_{e} = {e}^{2} / ( {m}_{e} {c}^{2} ) ,$$

with I₀=1.37 10¹⁸ W/cm², λ is the laser wavelength. [Ref 16]

Furthermore, in example embodiments, the design parameters for the accelerated deuteron beam is in the range of 30-200 keV. For this range the coulombic collision rate is 10× higher than the fusion rate. During one Coulomb collision a deuteron losses on average 4% of its energy, i.e., energy is transferred to the target, such as tritium. Therefore, the optimum deuteron energy is 200 keV, whereas we assumed 10 Coulomb collision before fusion takes place. The D-T fusion cross section is maximum—8 barns—at 60 keV.

The high repetition rated, highly efficient CAN laser [Ref. 12] is guided by a set of optics, see, e.g., the mirrors 220 (FIGS. 2A and 3A), to the nanometric foil target 224 (FIGS. 2B, 3B, 4A and 4B). The repetition rate of the intense laser pulses are 100 kHz delivered with high efficiency of 50%. Such a laser has previously been proposed as a diagnostic system [see, e.g., Ref 17]. A typical power of 200 kW is expected to delivery 10¹⁷ neutrons/s. Such a neutron flux is sufficient [see, e.g., Ref 17] to drive a 10 MW transmutator.

Laser driven neutron efficiency is shown in Table 1.

TABLE 1
For specified foil thickness and laser pulse length efficiency
for conversion of laser energy to deuteron energy is shown.

| Foil thickness [nm] | Pulse [fs] | Efficiency [%] |
|---|---|---|
| 10 | 100 | 1.6 |
| 10 | 45 | 3.6 |
| 10 | 20 | 7.5 |
| 10 | 15 | 9.7 |
| 10 | 8 | 18 |
| 5 | 45 | 1 |
| 5 | 20 | 2.2 |
| 5 | 15 | 3.2 |
| 5 | 5 | 10 |
| 3.5 | 2 | 50 |

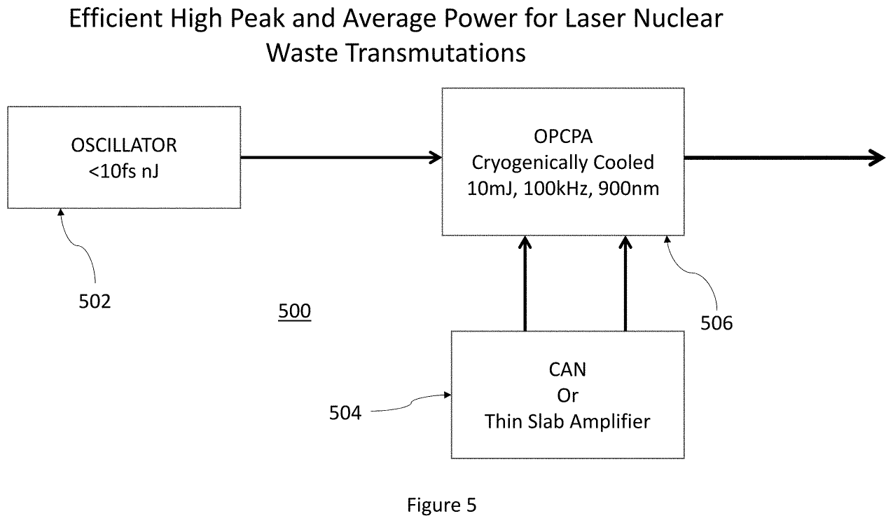

FIG. 5 illustrates details of the laser system 500 for the transmutator. The CPA [Ref 18] based XCAN 504 [Ref. 12; Ref. 19] will provide a high-energy high-pump pulse for the OPCPA 506. [Ref. 20] The pulse will be generated by XCAN laser making possible very high-pump pulse repetition rate up to 100 kHz. The femtosecond pulses are produced by a femtosecond oscillator 502 delivering over a million pulses per second After the oscillator, the pulses are picked up at the desired rate of up to 100 kHz before being stretched to a few nanoseconds. After stretching, the pulse is amplified in a cryogenic OPCPA to a level of tens of mega Joules. The amplified chirped pulse is then compressed back to its initial value of <10 fs.

The cryogenic OPCPA preferably exhibits an extremely high thermal conductivity comparable to copper, which is necessary to evacuate the tens of kilo Watts of thermal load produced during the optical parametric amplification process. With the spectral bandwidth corresponding to less than a 10 fs pulse, the pulse can be easily stretched to about one nanosecond and amplified by optical parametric amplification to 10 mJ. In the process the pulse is mixed with the pump pulse provided by the CAN system of about a ns duration and >10 mJ energy.

The transmutation laser combines four (4) laser technologies: CPA [Ref. 18], CAN [Ref 12; Ref. 19], OPCPA [Ref. 20; Ref 21], and cryo-cooled nonlinear crystals [Ref. 22]. As shown if FIG. 5, as an alternative, a thin disk amplifier [Ref. 23] could replace the CAN 504. The laser system for the transmutator is preferably able to:
a. Deliver a peak power corresponding to a₀=0.5 or intensity of about 5×10¹⁷ W/cm2 with a spot size of, e.g., 5 μm.
b. Produce pulses, e.g., <10 fs, 10 mJ, very high repetition rate in the range of 10-100 kHz or an average power that could reach 100 kW.

Additional features of the laser system for the transmutator include:
c. The OPCPA is adapted to average power. In order to cool the nonlinear crystal more efficiently in order to increase its thermal conductivity, the crystal is mounted on a cryogenically cooled heat sink. As mentioned earlier, at cryogenic temperature the crystal thermal conductivity at or less than liquid nitrogen temperature, increases dramatically, to reach the value of thermal conductivity of copper [Ref 22].
d. The OPCPA [Ref. 20; Ref 21] will make possible the generation of pulses in the 10 fs regime. When pumped by a CAN [Ref. 12; Ref. 19], Coherent Network Amplifier could possibly be utilized to amplify the seed pulse, e.g., to the 10 mJ level at 10-100 kHz.
e. For applications requiring, e.g., 100 kW or more, N identical systems are configurable in parallel. Such applications, however, do not require the lasers to be phased.
f. As an alternative for the CAN system, pumping of the amplifier could be replaced by a thin disk laser system [Ref 23].

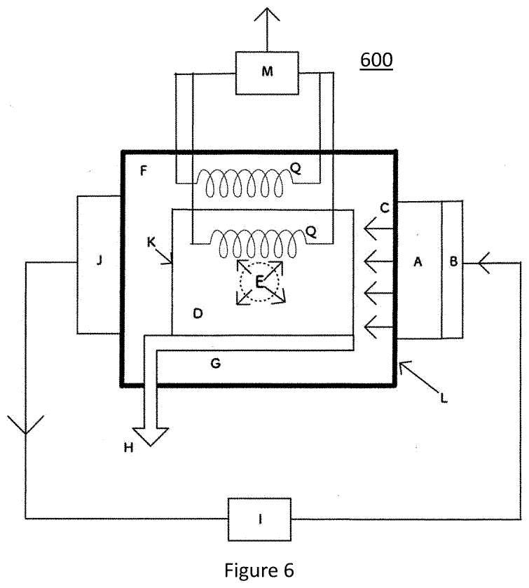

FIG. 6 shows a laser operation system 600 for the purposes of spectroscopy, active monitoring and fission product separation. Component A is the CAN laser (in bundles appropriately); component B is the modulator/controller of the CAN laser (controlling the laser properties such as the power level, amplitude shape, periods and phases, the relative operations, direction, etc.); component C is the laser rays irradiating the solution and solvents in the central tank (see component K) for both the monitoring and separation (or controlling the chemistry of the solvents); component D is the solution that contains solvents including the transuraniums (such as Am, Cm, Np) ions that are to be separated and transmuted by the transmutator E [Ref 5] (emanating fusion produced high energy neutrons); component F is the water that stops the neutrons both from the fusion source, i.e., transmutator E, and from the fission products; component G is the precipitation that is to be taken out of the deposit at the bottom of the central tank (as an example of a separation by laser chemistry in the central tank where solution is contained); component H is the unnecessary deposited elements that are not to be transmuted at this time in this particular tank and to be transferred to another tank, where they will be again in the solution similar to this to be further separated and transmuted; component I is the feedback ANN circuit and computer that registers and controls the signal of the monitored information such as spectrum of the FP; component J is the detector of the transmitted CAN laser signals (amplitudes, phases and frequencies, and deflections, etc.); component K is the “thin” first wall of the central tank that allow nearly free transmission of the energetic neutrons generated either by fusion or fission in the central tank, and component L is the outer tank with a thick enough wall that contains overall materials and neutrons. Both the central tank K and the outer tank L are equipped with appropriate monitors of the temperature, pressure, and some additional physical and chemical information in addition to the CAN laser monitoring to monitor, and provide alerts regarding, the transmutator's condition to keep the tanks from going over the “board” (such as runaway events) with appropriate safeguards such as the real-timed valves, electrical switches, etc. Component Q is a heat exchanger and component M converts heat to electricity.

Once the operation begins, the heated solution and water in the central and outer tanks K and L may be maintained in its state by motors (or perhaps appropriate channels inside the tanks, or equivalents) as desired, and excess heat is taken out and converted into electrical (or chemical) energies by component M.

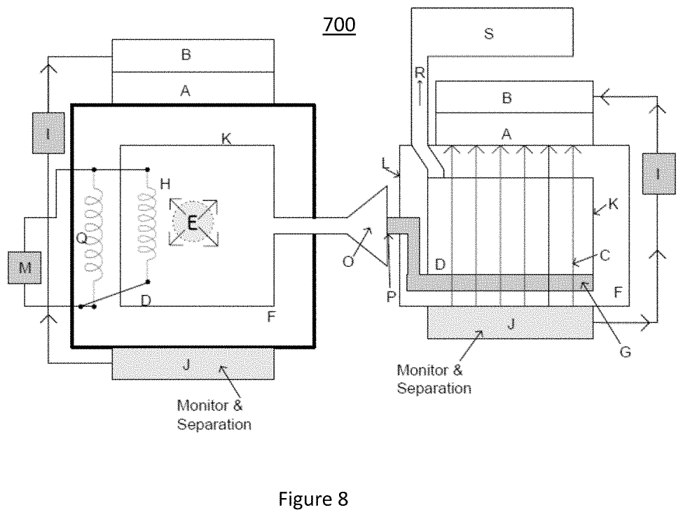

Referring to FIG. 8, in a system 800, component P is the pipe (and its valve that controls the flow between the tanks) connecting the segregated separator tank and the transmutator tank. Component O is a solving region of the injected separated MA into the transmutator tank. The residual fission products left in component D are transported out through the pipe component R into a storage tank component S.

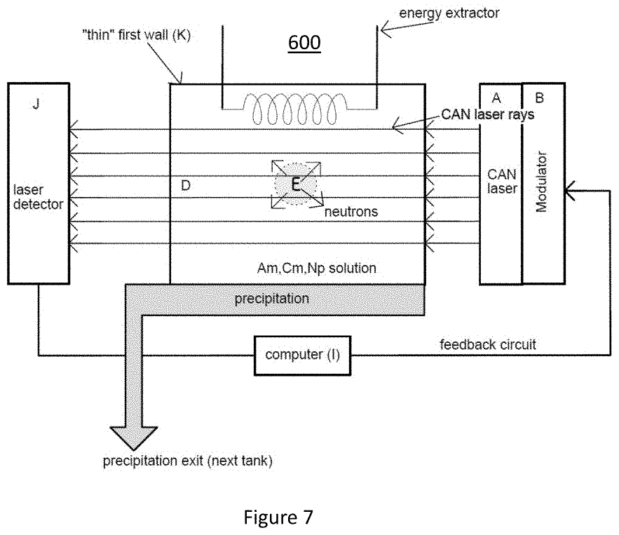

Referring to FIG. 7, in a system 700, the central tank K contains the solution D of the transuraniums that were extracted from the original spent fuel that has been liquefied with proper solutions (such as acids). In this stage of the process, we assume that U and Pu have been already extracted from the solution D by known processes (such as PUREX). The solution D may thus include other elements such as fission products (FPs such as Cs, Sr, I, Zr, Tc, etc.). These elements can tend to absorb neutrons, but not necessarily proliferate neutrons as the transuraniums tend to do. Thus, the FPs need to be eliminated from the solution D in the central tank K by chemical reactions and laser chemistry, etc., with the help of the CAN laser A and other chemical means. If these elements precipitate by the added chemical and/or chemical excitation etc. from the CAN laser, the precipitated components of chemicals may be removed from this central tank K to another tank for the treatment of such elements as the fission products etc.

Upon completion of the separation process, the transuraniums (mainly Am, Cm, Np) are irradiated with neutrons from the transmutator E. These transuraniums may have different isotopes, but all of them are radioactive isotopes, as they are beyond uranium in their atomic number. Either neutrons from the transmutator E or neutrons arising from the fissions of the transuraniums will contribute to the transmutation of the transuraniums if neutrons are absorbed by these nuclei.

Turning to FIG. 8, the transmutator and laser monitor and separator system 800 includes two separate tanks segregating the separation and transmutation processes into two distinct tanks. For example, the separator (with laser monitor attached) is on the right, while the transmutator is on the left. The two systems are connected by a transmission pipe and valve, component P, which is used to transmit the deposited (or separated) transuraniums (MA) from the separator tank on the right into the transmutator tank on the left. The new carrier liquid (component O) preferably only contains (or primarily contains) TA, but not any more fission products that have been separated in the separator tank on the right. Separation is accomplished by either conventional chemical method or by laser (based on CAN laser), which operates to excite (for example) the MA atomic electrons for the purpose of chemical separation. The central tank D on the left has primarily (or only) MA solution. The elements left out of the liquid contain mainly FPs that are transported in a pipe (component R) into a storage tank (component S). Such FPs may be put together into solidified materials for burial treatment. [Refs. 22 and 23]

When fission occurs by the neutron capture by the transuraniums, a high-energy yield from the nuclear fission is typically expected (such as in the range of 200 MeV per fission). On the other hand, the fusion neutron energy does not exceed 15 MeV. Both the fusion neutrons as well as the fission events in the central tank yield heat in the tank. The solution mixes the heat in general by the convective flows (either by itself or, if necessary, by an externally driven motor). The extracted heat transporter and extractor, i.e. component M, remove the generated heat in the central tank and convert it into electric energy. These processes need to be monitored both physically (such as the temperature, pressure of the solution in the tank) and chemically (such as the chemical states of various molecules, atoms, and ions in the solution through the CAN laser monitoring) in real time for the monitoring and control purpose to feedback to the tank parameters by controlling valves and other knobs as well as the CAN operation.

A typical nuclear reactor generates the following spent fuel nuclear wastes. [Refs. 22 and 23] Per 1 ton of uranium which generates 50 GWd of power. During this operation the nuclear wastes are: about 2.5 kg of transuraniums (Np, Am, Cm) and about 50 kg of fission products. The amount of 2.5 kg of MA (Minor Actinides, i.e. transuraniums) is about 100 mol, approximately 6×1025 atoms of MA. This amounts to about 7×1020 atoms of MA per second, approximately 1021 MA atoms in 1 sec. This translates into about 1 kW of laser power if the absorption of one photon (eV) by each MA atom in order to laser excite each atom is required. Let η be the efficiency of excitation of an MA atom by 1 photon of laser. Then the power P of the laser to be absorbed by all MA atoms of the above amount per second is

P˜(1/η)kW.

If η˜0.01, P is about 100 kW. This amount is not small. On the other hand, borrowing efficient and large fluence CAN laser technology [Ref 12], it is within the realm of the technology reach. In typical chemical inducements, we envision that the laser may be either close to cw, or very long pulse so that the fiber laser efficiency and fluence are at its maximum. In order to satisfy the proper resonances or specific frequencies, the fiber laser frequencies need to be tuned (prior to the operation, most likely) to the specific values.

As further example embodiments, the high efficiency neutron generation method is applicable to fields and processes requiring neutrons having energy up to 14 MeV, such as, e.g., cancer medical applications such as, e.g., boron-neutron capture therapy (BNCT) and radioisotope generation, structural integrity testing of buildings, bridges, etc., material science and chip testing, oil well logging and the like.

Two additional embodiments are presented: (1) a first embodiment directed to a 2-tank strategy to reduce the overall neutron cost whereas Tank 1 is critical and Tank 2 subcritical, and (2) second embodiment directed toward a greener, carbon negative trasmutator through the generation of synthetic fuel by the chemical conversion of CO_2 whereas the heat to drive the reaction is generated by fission.

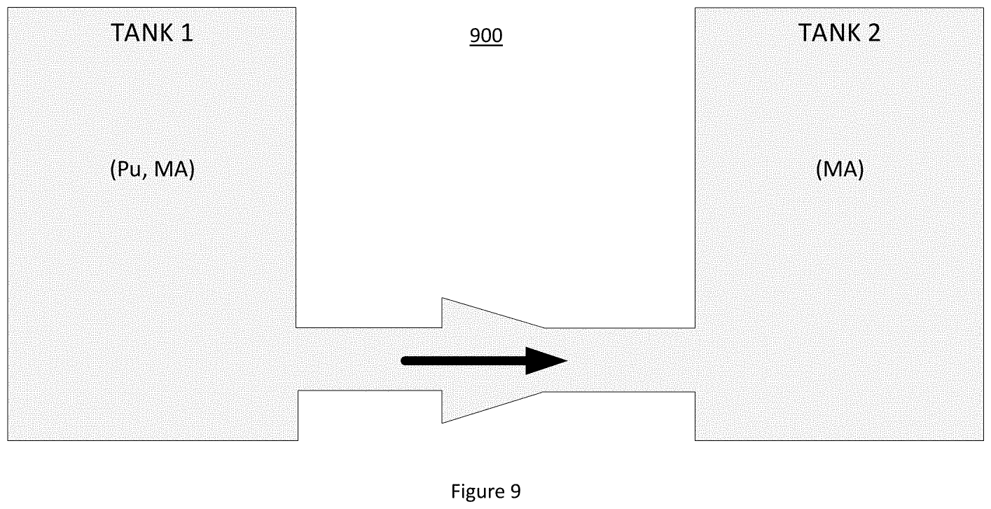

In an example embodiment depicted in FIG. 9, the transmutator 900 comprises two interconnected sets of tanks referred to as Tank 1 and Tank 2. Tanks 1 and 2, which are substantially similar to the tanks depicted in FIGS. 2A and 3A, may include a tank containing materials to be transmuted and a neutron source tank positioned therein, and as depicted in FIGS. 1A and 1B, these tanks may be enclosed by additional concentric tanks. Tank 1 preferably contains a mixture of Pu and minor actinides (MA) including neptunium, americium and curium (Np, Am, Cm), while Tank 2 contains a mixture of only minor actinides (MA). Tank 1 is critical (k_{eff}=1), hence Tank 1 does not require external neutrons. Furthermore, Tank 1 is fueled using the spent nuclear fuel (Pu and MA) after chemical removal of fission products. Tank 1 utilizes fast neutrons (fusion neutrons in addition to unmoderated fission neutrons with energy >1 MeV) to transmute the minor actinides (MA) and plutonium (Pu), while the concentration of curium (Cm) is increased. Alternatively, a minor amount of neutrons can be injected into Tank 1 to kick start the incineration of Pu.

The minor actinides (MA) in Tank 1, now with higher concentration of curium (Cm), may be separated and fed into Tank 2. The connected Tank 2 operates in parallel to burn the minor actinides (MA) with the increased concentration of curium (Cm) in a subcritical (k_{eff}<1) operation, as described above. This process provides a path to safely and smoothly burn the entire transuranic spent nuclear fuel (not just MAs) while reducing the number of neutrons required to do so by about a factor of 100×.

In a further embodiment, Tank 1 and Tank 2 are real-time monitored by laser and gamma. A broadband or a scanning laser is used to monitor the elemental composition of Tank 1 and Tank 2 using the laser induced fluorescence and scattering. Gamma monitoring can be either active or passive. Passive gamma monitoring utilizes gamma generated from nuclear decay or transition. Active gamma monitoring utilizes external gamma beam with energy above few MeV and relies on the nuclear resonance fluorescence. Both active and passive monitoring provides information about the isotopic composition of the transmutator fuel. Information from the laser and the gamma monitoring is collected and fed into a computer comprising logic adapted to predict and/or control future states of the transmutator by adjusting the refueling of Tank 1 or adjusting the MA concentration in Tank 2. To enable the detailed laser and gamma monitoring the fuel in Tank 1 and Tank 2 is dissolved in a molten salt allowing for light propagation. Real time monitoring is an integral part of the overall active safety and efficiency of the transmutator whereas a detail knowledge of the transmutator composition will determine the position of the control rods, the refueling and fission product extraction. Passive features include molten salt that expands with increasing temperature thus shutting the transmutator down; dump tank separated from the transmutator by a freeze plug whereas any abnormal temperature spike will melt the plug and gravity flow the entire inventory of the transmutator into the dump tank composed of neutron absorbers.

In a further embodiment the walls of Tank 1 and Tank 2 are made of carbon based materials, e.g., diamond. To protect walls from chemical erosion and corrosion, the salt adjacent to the wall (facing the molten salt) is allowed to solidify preventing direct contact of the molten salt with the walls.

In a further embodiment, the transmutator embodiments described above can be applied to the methods and processes of carbon dioxide reduction such as its use as a coolant and its generation of a synthetic fuel to become overall carbon-negative is suggested. In the following example embodiment, the synthetic fuel (CH₄—methane) may be generated via CO₂+4H₂→CH₄+2H₂O reaction (Sabatier reaction) requiring 200-400° C. and the presence of a catalyst, e.g., Ni, Cu, Ru. The CO₂ may be extracted from the atmosphere, the ocean, or by direct capturing of CO₂ at the source of emission such as automobiles, houses, chimneys and smokestacks. The molten salt transmutator operating temperature range is 250-1200° C. and, thus, is ideally situated to supply continuously the necessary temperature required to drive the Sabatier reaction to produce methane, and provide an effective pathway to stabilize and reduce the CO₂ concentration in the atmosphere and the ocean.

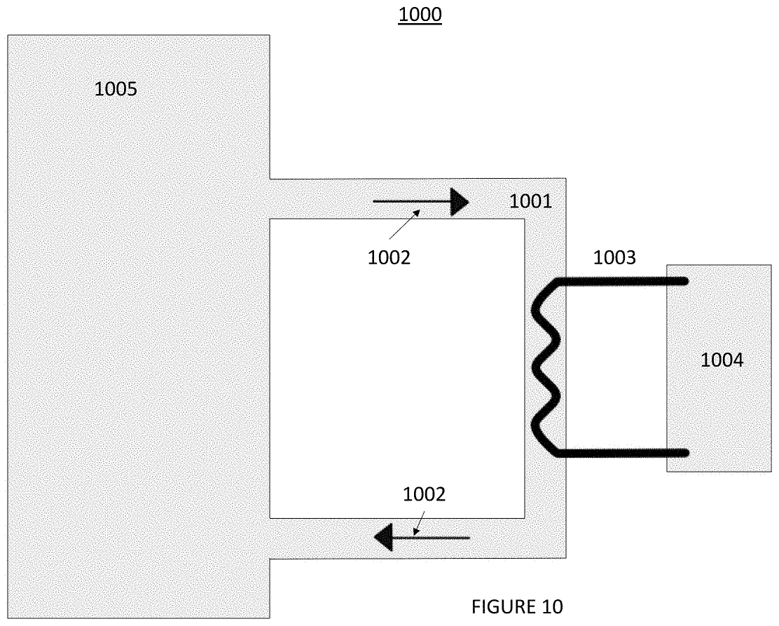

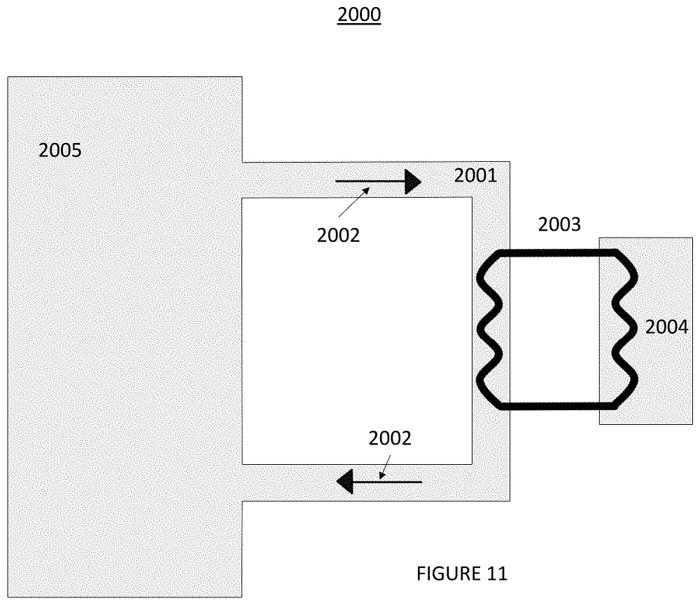

Referring to FIG. 10, a partial view of a synthetic fuel generation system 1000 is shown to include a transmutator vessel 1005, a secondary loop pipe 1001, the direction of the flow of the molten salt+TRU 1002, a heat exchanger 1003, and a tank for the Sabatier reaction 1004. In this example embodiment, the heat transfer fluid in the heat exchanger pipe is CO2 which is directly used in the tank 1004. In an alternative embodiment, shown in FIG. 11, the heat exchange pipe of the heat exchanger 2003 of a synthetic fuel generation system 2000 is a closed and independent system, and the transfer fluid may be replaced with a molten salt. The synthetic fuel generation system 2000 is shown to include a transmutator vessel 2005, a secondary loop pipe 2001, the direction of the flow of the molten salt+TRU 2002, a heat exchanger 2003, and a tank for the Sabatier reaction 2004.

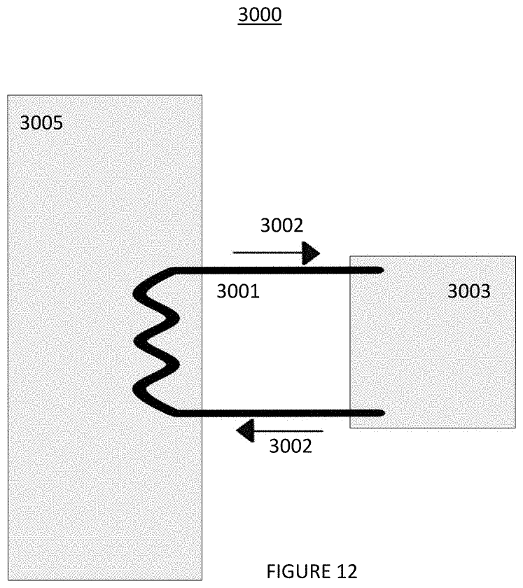

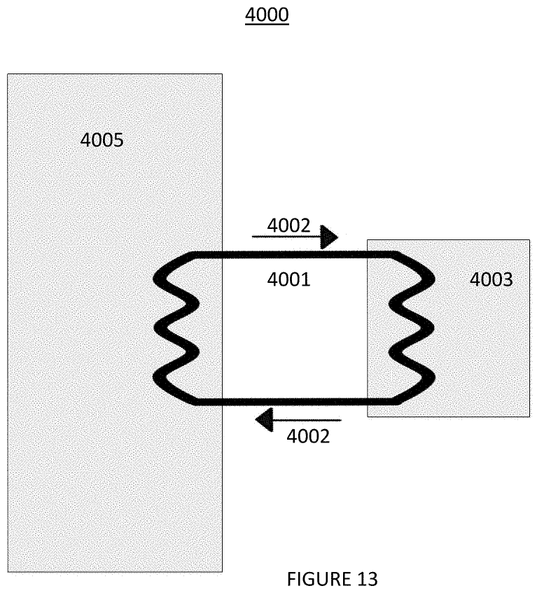

In a further alternative embodiment, FIG. 12 shows a partial view of a synthetic fuel generation system 3000 having a transmutator 3005, a heat exchanger 3001, the direction of the flow of the fluid 3002, and a tank for the Sabatier reaction 3003. In this example embodiment, the reactant, CO₂, from the Sabatier reaction is the transfer fluid. In an alternative embodiment, FIG. 13 shows the heat exchanger loop 4001 of a synthetic fuel generation system 4000 as closed and independent loop with the heat transfer fluid being, for example, a molten salt. The synthetic fuel generation system 4000 is shown to include a transmutator 4005, a heat exchanger 4001, the direction of the flow of the fluid 4002, and a tank for the Sabatier reaction 4003.

In an additional embodiment, ionizing radiation originating within the transmutator and carried by the molten salt is utilized as a 1-10 s eV energy source to enable various chemical reactions. The 1-10 eV energy source enables, for example, the production of ammonia and conversion of CO_2+CH_4→CH_3 COOH.

Processing circuitry for use with embodiments of the present disclosure can include one or more computers, processors, microprocessors, controllers, and/or microcontrollers, each of which can be a discrete chip or distributed amongst (and a portion of) a number of different chips. Processing circuitry for use with embodiments of the present disclosure can include a digital signal processor, which can be implemented in hardware and/or software of the processing circuitry for use with embodiments of the present disclosure. In some embodiments, a DSP is a discrete semiconductor chip. Processing circuitry for use with embodiments of the present disclosure can be communicatively coupled with the other components of the figures herein. Processing circuitry for use with embodiments of the present disclosure can execute software instructions stored on memory that cause the processing circuitry to take a host of different actions and control the other components in figures herein.

Processing circuitry for use with embodiments of the present disclosure can also perform other software and/or hardware routines. For example, processing circuitry for use with embodiments of the present disclosure can interface with communication circuitry and perform analog-to-digital conversions, encoding and decoding, other digital signal processing and other functions that facilitate the conversion of voice, video, and data signals into a format (e.g., in-phase and quadrature) suitable for provision to communication circuitry, and can cause communication circuitry to transmit the RF signals wirelessly over links.

Communication circuitry for use with embodiments of the present disclosure can be implemented as one or more chips and/or components (e.g., transmitter, receiver, transceiver, and/or other communication circuitry) that perform wireless communications over links under the appropriate protocol (e.g., Wi-Fi, Bluetooth, Bluetooth Low Energy, Near Field Communication (NFC), Radio Frequency Identification (RFID), proprietary protocols, and others. One or more other antennas can be included with communication circuitry as needed to operate with the various protocols and circuits. In some embodiments, communication circuitry for use with embodiments of the present disclosure can share an antenna for transmission over links. Processing circuitry for use with embodiments of the present disclosure can also interface with communication circuitry to perform the reverse functions necessary to receive a wireless transmission and convert it into digital data, voice, and video. RF communication circuitry can include a transmitter and a receiver (e.g., integrated as a transceiver) and associated encoder logic. A reader can also include communication circuitry and interfaces for wired communication (e.g., a USB port, etc.) as well as circuitry for determining the geographic position of reader device (e.g., global positioning system (GPS) hardware).

Processing circuitry for use with embodiments of the present disclosure can also be adapted to execute the operating system and any software applications that reside on a reader device, process video and graphics, and perform those other functions not related to the processing of communications transmitted and received. Any number of applications (also known as “user interface applications”) can be executed by processing circuitry on a dedicated or mobile phone reader device at any one time, and may include one or more applications that are related to a diabetes monitoring regime, in addition to the other commonly used applications, e.g., smart phone apps that are unrelated to such a regime like email, calendar, weather, sports, games, etc.

Memory for use with embodiments of the present disclosure can be shared by one or more of the various functional units present within a reader device, or can be distributed amongst two or more of them (e.g., as separate memories present within different chips). Memory can also be a separate chip of its own. Memory can be non-transitory, and can be volatile (e.g., RAM, etc.) and/or non-volatile memory (e.g., ROM, flash memory, F-RAM, etc.).

Computer program instructions for carrying out operations in accordance with the described subject matter may be written in any combination of one or more programming languages, including an object oriented programming language such as Java, JavaScript, Smalltalk, C++, C#, Transact-SQL, XML, PHP or the like and conventional procedural programming languages, such as the “C” programming language or similar programming languages. The program instructions may execute entirely on the user's computing device (e.g., reader) or partly on the user's computing device. The program instructions may reside partly on the user's computing device and partly on a remote computing device or entirely on the remote computing device or server, e.g., for instances where the identified frequency is uploaded to the remote location for processing. In the latter scenario, the remote computing device may be connected to the user's computing device through any type of network, or the connection may be made to an external computer.

Various aspects of the present subject matter are set forth below, in review of, and/or in supplementation to, the embodiments described thus far, with the emphasis here being on the interrelation and interchangeability of the following embodiments. In other words, an emphasis is on the fact that each feature of the embodiments can be combined with each and every other feature unless explicitly stated otherwise or logically implausible.

According to embodiments, a transmutator system for transmutation of long-lived radioactive transuranic waste comprises a neutron source tank including a neutron source therein, where the neutron source comprising a plurality of carbon nanotubes (CNTs) saturated with tritium, a plurality of pre-pulse lasers configured to irradiate and penetrate the neutron source tank with laser energy in the Above-Threshold Ionization regime for ionizing the CNTs and tritium and maintain the ionized gas of carbon and tritium at almost solid density for a predetermine period of time, a plurality of concentric tanks positioned about the neutron source tank and comprising a one or more mixtures of long-lived radioactive transuranic waste dissolved in FLiBe salt, a laser system oriented to axially propagate a plurality of laser pulses into the neutron source, and a plurality of keyholes oriented to axially receive the plurality of laser pulses, each of the plurality of keyholes including a foil member of deuterated material, wherein upon irradiation of the foil member by a laser pulse of the plurality of laser pulses, the foil member produces a plurality of deuteron ions acceleratable as an ion beam in a direction toward the center of the neutron source tank where the deuteron beam fuses with the ionized tritium plasma at near solid density.

In embodiments, the foil member comprises a deuterated diamond-like material, and the plurality of ions includes deuteron and carbon ions.

In embodiments, the plurality of ions are accelerated by coherent acceleration of ions (CAIL) acceleration.

In embodiments, the foil member is one or more nano-meters thick.

In embodiments, the pulse from the laser and the pre-pulse lasers are synchronized to allow the deuteron beam to lag the ionization of the tritium.

In embodiments, the plurality of pre-pulse lasers include a first set of pre-pulse lasers and a second set of pre-pulse lasers.

In embodiments, the first set of pre-pulse lasers is configured to fire prior to the second set of pre-pulse lasers.

In embodiments, the laser system includes a plurality of mirrors oriented to direct individual laser pulses of the plurality of laser pulses toward and into individual keyholes of the plurality of keyholes.

In embodiments, the plurality of concentric tanks are segmented.

In embodiments, the plurality of concentric tanks are segmented axially.

In embodiments, the plurality of concentric tanks are segmented azimuthally.

In embodiments, the plurality of segmented tanks comprise a first concentric tank positioned about the neutron source and comprising a first mixture of long-lived radioactive transuranic waste dissolved in FLiBe salt, a second concentric tank positioned about the first concentric tank and comprising a second mixture of long-lived radioactive transuranic waste dissolved in FLiBe salt, a third concentric tank positioned about the second concentric tank and comprising a third mixture of long-lived radioactive transuranic waste dissolved in FLiBe salt, and a fourth concentric tank positioned about the third concentric tank and comprising one of water or water and a neutron reflecting boundary.

In embodiments, the segmented first, second, third and fourth concentric tanks are segmented axially.

In embodiments, the segmented first, second, third and fourth concentric tanks are segmented azimuthally.

In embodiments, the laser system includes one of a CAN laser or a thin slab amplifier.

In embodiments, the laser system further includes an OPCPA coupled to the CAN laser or thin slab amplifier, and an oscillator coupled to the OPCPA.

In embodiments, the OPCPA is cryogenically cooled.

In embodiments, the plurality of concentric tanks form a first set of tanks, wherein the transmutator system further comprising a second set of tanks containing a mixture of Pu and minor actinides (MA) including neptunium, americium and curium (Np, Am, Cm).

In embodiments, the second set of tanks are configured to operate at critical.

In embodiments, the walls of one of the first set of tanks or the second set of tanks are made of carbon based materials.

In embodiments, the carbon based materials are diamond.

It should be noted that all features, elements, components, functions, and steps described with respect to any embodiment provided herein are intended to be freely combinable and substitutable with those from any other embodiment. If a certain feature, element, component, function, or step is described with respect to only one embodiment, then it should be understood that that feature, element, component, function, or step can be used with every other embodiment described herein unless explicitly stated otherwise. This paragraph therefore serves as antecedent basis and written support for the introduction of claims, at any time, that combine features, elements, components, functions, and steps from different embodiments, or that substitute features, elements, components, functions, and steps from one embodiment with those of another, even if the following description does not explicitly state, in a particular instance, that such combinations or substitutions are possible. It is explicitly acknowledged that express recitation of every possible combination and substitution is overly burdensome, especially given that the permissibility of each and every such combination and substitution will be readily recognized by those of ordinary skill in the art.

To the extent the embodiments disclosed herein include or operate in association with memory, storage, and/or computer readable media, then that memory, storage, and/or computer readable media are non-transitory. Accordingly, to the extent that memory, storage, and/or computer readable media are covered by one or more claims, then that memory, storage, and/or computer readable media is only non-transitory.

As used herein and in the appended claims, the singular forms “a,” “an,” and “the” include plural referents unless the context clearly dictates otherwise.

While the embodiments are susceptible to various modifications and alternative forms, specific examples thereof have been shown in the drawings and are herein described in detail. It should be understood, however, that these embodiments are not to be limited to the particular form disclosed, but to the contrary, these embodiments are to cover all modifications, equivalents, and alternatives falling within the spirit of the disclosure. Furthermore, any features, functions, steps, or elements of the embodiments may be recited in or added to the claims, as well as negative limitations that define the inventive scope of the claims by features, functions, steps, or elements that are not within that scope.

### REFERENCES

[Ref. 1] https://www.gao.gov/key_issues/disposal_of_highlevel_nuclear_waste/issue_summary Accessed Oct. 23, 2018.

[Ref. 2] Gulik, V., & Tkaczyk, A. H., Cost optimization of ADS design: Comparative study of externally driven heterogeneous and homogeneous two-zone subcritical reactor systems. Nuclear Engineering and Design, 270, 133-142 (2014).

[Ref. 3] Weston M. Stacey, Solving the Spent Nuclear Fuel Problem by Fissioning Transuranics in Subcritical Advanced Burner Reactors Driven by Tokamak Fusion Neutron Sources, Nuclear Technology, (2017). DOI: 10.1080/00295450.2017.1345585

[Ref. 4] Sheu, R. J., et al “Depletion analysis on long-term operation of the conceptual Molten Salt Actinide Recycler & Transmuter (MOSART) by using a special sequence based on SCALE6/TRITON.” Annals of Nuclear Energy 53 (2013): 1-8.

[Ref. 5] Tajima T. and Necas A., “Systems And Methods For Frc Based Transmutator And Radioisotope Generator,” U.S. Patent Application Ser. No. 62/544,666, Aug. 11, 2017.

[Ref. 6] Tajima, Toshiki, Dietrich Habs, and Xueqing Yan. “Laser acceleration of ions for radiation therapy.” Reviews of Accelerator Science and Technology 2.01 (2009): 201-228.

[Ref. 7] Kishimoto, Y., and Tajima, T., Strong Coupling between Clusters and Radiation, High Field Science, eds. T. Tajima, K. Mima, and H. Baldis (Kluwer, N.Y., 2000).pp 83-96.

[Ref. 8] Kishimoto, Y., Masaki, T., and Tajima, T., High energy ions and nuclear fusion in laser-cluster interaction, Phys. of Plasmas 9, 589-601(2002).

[Ref. 9] Yan, X. Q., Tajima, T., Hegelich, B. M., Yin, L., and Habs, D., Theory of laser ion acceleration from a foil target of nanometer thickness, Applied Phys. B 98, 711 (2010).

[Ref. 10] Mako, F., and T. Tajima. “Collective ion acceleration by a reflexing electron beam: Model and scaling.” The Physics of fluids 27, no. 7: 1815-1820 (1984).

[Ref. 11] Steinke, S., Henig, A., Schnürer, M., Sokollik, T., Nickles, P. V., Jung, D., Kiefer, D., Hörlein, R., Schreiber, J., Tajima, T. and Yan, X. Q., Efficient ion acceleration by collective laser-driven electron dynamics with ultra-thin foil targets. Laser and Particle Beams, 28(1), pp.215-221 (2010).

[Ref. 12] Mourou, G., Brocklesby, B., Tajima, T. and Limpert, J., The future is fibre accelerators. Nature Photonics, 7(4), p.258 (2013).

[Ref. 13] Mourou, G., S. Mirnov, E. Khazanov, and A. Sergeev. “Single cycle thin film compressor opening the door to Zeptosecond-Exawatt physics.” The European Physical Journal Special Topics 223, no. 6: 1181-1188 (2014).

[Ref. 14] Zhou, M. L., Yan, X. Q., Mourou, G., Wheeler, J. A., Bin, J. H., Schreiber, J. and Tajima, T., 2016. Proton acceleration by single-cycle laser pulses offers a novel monoenergetic and stable operating regime. Physics of Plasmas, 23(4), p.043112 (2016).

[Ref. 15] Tajima, T., “Laser driven compact ion accelerator,” U.S. Pat. No. 6,867,419, issued Mar. 15, 2005.

[Ref. 16] Esirkepov, T., M. Yamagiwa, and T. Tajima. “Laser ion-acceleration scaling laws seen in multiparametric particle-in-cell simulations.” Physical review letters 96, no. 10 (2006): 105001.

[Ref. 17] Tajima T., Mourou G. and Necas A., “Systems And Methods For Liquid Phase Based Transmutation With Can Laser Based Monitoring,” U.S. Patent Application Ser. No. 62/665,287, May 1, 2018.

[Ref. 18] D. Strickland and G. Mourou, “Compression of Amplified Chirped Optical Pulses,” Opt. Commun. 56, 219-221 (December 1985).

[Ref. 19] G. Mourou and J. Nees “Selectively Triggered High-Contrast Laser”, U.S. Pat. No. 5,541,947, issued Jul. 30, 1996.

[Ref. 20] A. Dubietis, G. Jonus̆auskas, and A. Piskarskas, “Powerful femtosecond pulse generation by chirped and stretched pulse parametric amplification in BBO crystal,” Opt. Commun. 88(4-6), 437-440 (1992).

[Ref. 21] R. Budrinuas, T. Stanislauskas, J. Adamonis, A. Alecknavicius, G. Veitas, G. Stanislovas-Balickas, A. Michailova, and A. Varanaci-Iusi, 53 W average power CEP-stabilized OPCPA, system delivering 5.5 TW few cycle pulses at 1 kHz repetition rate, Vol. 25, No. 5|6 Mar 2017|OPTICS EXPRESS 5797

[Ref. 22] S. Backus, C. Durfee, G. Mourou, H. C. Kapteyn, M. M. Murnane, 0.2 Terawatt laser system at 1 kHz, Opt. Lett. 22, 1256 (1997).

[Ref. 23] A. Giesen and J. Speiser, “Fifteen years of work on thin-disk lasers: results and scaling laws”, IEEE J. Sel. Top. Quantum Electron. 13 (3), 598 (2007).

What is claimed:

1. A transmutator system for transmutation of long-lived radioactive transuranic waste comprising:
a neutron source tank including a neutron source therein, where the neutron source comprising a plurality of carbon nanotubes (CNTs) saturated with tritium;
a plurality of pre-pulse lasers configured to irradiate and penetrate the neutron source tank with laser energy in the Above-Threshold Ionization regime for ionizing the CNTs and tritium and maintain the ionized gas of carbon and tritium at almost solid density for a predetermine period of time,
a plurality of concentric tanks positioned about the neutron source tank and comprising a one or more mixtures of long-lived radioactive transuranic waste dissolved in FLiBe salt;
a laser system oriented to axially propagate a plurality of laser pulses into the neutron source; and
a plurality of keyholes oriented to axially receive the plurality of laser pulses, each of the plurality of keyholes including a foil member of deuterated material, wherein upon irradiation of the foil member by a laser pulse of the plurality of laser pulses, the foil member produces a plurality of deuteron ions acceleratable as an ion beam in a direction toward the center of the neutron source tank where the deuteron beam fuses with the ionized tritium plasma at near solid density.

2. The transmutator system of claim 1, wherein the foil member comprises a deuterated diamond-like material, and the plurality of ions includes deuteron and carbon ions.

3. The transmutator system of claim 1, wherein the plurality of ions are accelerated by coherent acceleration of ions (CAIL) acceleration

4. The transmutator system of claim 1, wherein the foil member is one or more nano-meters thick.

5. The transmutator system of claim 1, wherein the pulse from the laser and the pre-pulse lasers are synchronized to allow the deuteron beam to lag the ionization of the tritium.

6. The transmutator system of claim 1, wherein the plurality of pre-pulse lasers include a first set of pre-pulse lasers and a second set of pre-pulse lasers.

7. The transmutator system of claim 6, wherein the first set of pre-pulse lasers is configured to fire prior to the second set of pre-pulse lasers.

8. The transmutator system of claim 1, wherein the laser system includes a plurality of mirrors oriented to direct individual laser pulses of the plurality of laser pulses toward and into individual keyholes of the plurality of keyholes.

9. The transmutator system of claim 1, wherein the plurality of concentric tanks are segmented.

10. The transmutator system of claim 9, wherein the plurality of concentric tanks are segmented axially.

11. The transmutator system of claim 9, wherein the plurality of concentric tanks are segmented azimuthally.

12. The transmutator system of claim 1, wherein the plurality of concentric tanks comprise:
a first concentric tank positioned about the neutron source and comprising a first mixture of long-lived radioactive transuranic waste dissolved in FLiBe salt;
a second concentric tank positioned about the first concentric tank and comprising a second mixture of long-lived radioactive transuranic waste dissolved in FLiBe salt;
a third concentric tank positioned about the second concentric tank and comprising a third mixture of long-lived radioactive transuranic waste dissolved in FLiBe salt; and
a fourth concentric tank positioned about the third concentric tank and comprising one of water or water and a neutron reflecting boundary.

13. The transmutator system of claim 12, wherein the first, second, third and fourth concentric tanks are segmented axially.

14. The transmutator system of claim 12, wherein the first, second, third and fourth concentric tanks are segmented azimuthally.

15. The transmutator system of claim 1, wherein the laser system includes one of a CAN laser or a thin slab amplifier.

16. The transmutator system of claim 15, wherein the laser system further includes an OPCPA coupled to the CAN laser or thin slab amplifier, and an oscillator coupled to the OPCPA.

17. The transmutator system of claim 16, wherein the OPCPA is cryogenically cooled.

18. The transmutator system of claim 1, wherein the plurality of concentric tanks form a first set of tanks, wherein the transmutator system further comprising a second set of tanks containing a mixture of Pu and minor actinides (MA) including neptunium, americium and curium (Np, Am, Cm).

19. The transmutator system of claim 18, wherein the second set of tanks are configured to operate at critical.

20. The transmutator system of claim 18, wherein the walls of one of the first set of tanks or the second set of tanks are made of carbon based materials.

21. The transmutator system of claim 20, wherein the carbon based materials are diamond.
